(19) United States
(12) Patent Application Publication
(10) Pub. No.: US 2025/0020728 A1
(43) Pub. Date: Jan. 16, 2025

(54) IMPEDANCE MEASUREMENT APPARATUS FOR SECONDARY BATTERY

(71) Applicant: DENSO CORPORATION, Kariya-City (JP)

(72) Inventors: Masaaki KITAGAWA, Kariya-City (JP); Isao ISHIBE, Kariya-City (JP); Kazuo MATSUKAWA, Kariya-City (JP); Shuhei YOSHIDA, Kariya-City (JP); Masaki UCHIYAMA, Kariya-City (JP)

(73) Assignee: DENSO CORPORATION, Kariya-City (JP)

(21) Appl. No.: 18/901,670

(22) Filed: Sep. 30, 2024

Related U.S. Application Data
(63) Continuation of application No. PCT/JP2023/007863, filed on Mar. 2, 2023.

(30) Foreign Application Priority Data
Mar. 30, 2022 (JP) 2022-056503

(51) Int. Cl. G01R 31/389; G01R 31/367; G01R 31/387; G01R 31/392; H01M 10/48; H02J 7/00

(52) U.S. Cl. CPC G01R 31/389; G01R 31/367; G01R 31/387; G01R 31/392; H01M 10/486; H02J 7/0063

(57) ABSTRACT

An impedance measurement apparatus is provided for measuring impedance of a secondary battery. The impedance measurement apparatus includes a measurement unit and a switching unit. The measurement unit is capable of measuring the impedance of the secondary battery using a plurality of measurement modes differing in measurement condition. The switching unit is configured to switch between the plurality of measurement modes based on a comparison between a correlating parameter, which correlates with the impedance of the secondary battery, and a threshold value.

### CROSS-REFERENCE TO RELATED APPLICATIONS

The present application is a continuation application of International Application No. PCT/JP2023/007863 filed on Mar. 2, 2023, which is based on and claims priority from Japanese Patent Application No. 2022-056503 filed on Mar. 30, 2022. The entire contents of these applications are incorporated by reference into the present application.

### BACKGROUND

### 1. Technical Field

The present disclosure relates to apparatuses that measure impedances of secondary batteries.

### 2. Description of Related Art

Conventionally, there is known an apparatus that measures the complex impedance of a secondary battery with respect to a plurality of frequencies within a measurement range, creates a complex impedance plane plot (Cole-Cole plot, Bode plot or the like) based on the measurement results, and ascertains the characteristics of the electrodes, electrolyte, etc. of the secondary battery (see, for example, Japanese Patent Application Publication No. JP 2020-180949 A).

### SUMMARY

In order to accurately ascertain the characteristics of the electrodes, electrolyte, etc. of a secondary battery, it is desirable to create a complex impedance plane plot with high accuracy. To this end, it is necessary to measure the complex impedance of the secondary battery with respect to more frequencies and to increase the number of measurements with respect to each frequency. However, in this case, the measurement time may become long and the electric current consumption of the secondary battery may become large.

The present disclosure has been accomplished in view of the above problem. It is, therefore, an object of the present disclosure to provide an impedance measurement apparatus for a secondary battery which can shorten the measurement time and/or reduce the electric current consumption of the secondary battery.

According to a first solution to the above problem, there is provided an impedance measurement apparatus for measuring impedance of a secondary battery. The impedance measurement apparatus comprises: a measurement unit capable of measuring the impedance of the secondary battery using a plurality of measurement modes differing in measurement condition; and a switching unit configured to switch between the plurality of measurement modes based on a comparison between a correlating parameter, which correlates with the impedance of the secondary battery, and a threshold value.

With the above configuration, the impedance measurement apparatus measures the impedance of the secondary battery. Here, the measurement unit is capable of measuring the impedance using a plurality of measurement modes differing in measurement condition. In general, the measurement time, the electric current consumption of the secondary battery and the electric current consumption of the measurement apparatus vary depending on the measurement condition. In this regard, the inventors of the present application have focused on the fact that there exist correlating parameters that correlate with the impedance and the measurement mode to be selected can be determined based on the correlating parameters.

The switching unit is configured to switch between the plurality of measurement modes based on a comparison between a correlating parameter, which correlates with the impedance of the secondary battery, and a threshold value. Consequently, by comparing the correlating parameter with the threshold value, it becomes possible to switch the measurement mode to a proper one of the plurality of measurement modes. As a result, it becomes possible to shorten the measurement time and/or reduce the electric current consumption of the secondary battery in comparison with the case of performing the measurement in a single measurement mode regardless of the correlating parameter. It should be noted that correlating parameters include the impedance itself in addition to various parameters correlating with the impedance.

In general, the measurement time and the electric current consumption of the secondary battery vary depending on the measurement method. In this regard, according to a second solution, the plurality of measurement modes differ in, as the measurement condition, method of measuring the impedance of the secondary battery by the measurement unit. Moreover, the switching unit is configured to switch between the plurality of measurement modes based on a comparison between a correlating parameter, which correlates with the impedance of the secondary battery, and a threshold value. Consequently, by comparing the correlating parameter with the threshold value, it becomes possible to switch the measurement mode to a proper one of the plurality of measurement modes differing in method of measuring the impedance.

According to a third solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, number of times of causing, by the current generation unit, the alternating current to be outputted from the secondary battery and measuring the voltage of the secondary battery by the voltage measurement unit.

With the above configuration, by setting the number of times of causing the alternating current to be outputted from the secondary battery and measuring the voltage of the secondary battery to be different between the plurality of measurement modes, it becomes possible to make the measurement accuracy, the measurement time and the electric current consumption of the secondary battery different between the plurality of measurement modes. Moreover, by comparing the correlating parameter with the threshold value, it becomes possible to switch the measurement mode to a proper one of the plurality of measurement modes differing in number of times of causing the alternating current to be outputted from the secondary battery and measuring the voltage of the secondary battery.

According to a fourth solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, number of bits of a digital value obtained by an AD conversion of an analog value of the voltage of the secondary battery measured by the voltage measurement unit.

With the above configuration, by setting the number of bits of the digital value obtained by the AD conversion of the analog value of the voltage of the secondary battery measured by the voltage measurement unit to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in number of bits of the digital value obtained by the AD conversion of the analog value of the voltage of the secondary battery measured by the voltage measurement unit.

According to a fifth solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, cutoff frequency of a low-pass filter that cuts off frequency components of the voltage of the secondary battery measured by the voltage measurement unit which are higher than the cutoff frequency.

With the above configuration, by setting the cutoff frequency of the low-pass filter to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in cutoff frequency of the low-pass filter.

According to a sixth solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, waveform of the alternating current caused by the current generation unit to be outputted from the secondary battery.

With the above configuration, by setting the waveform of the alternating current caused by the current generation unit to be outputted from the secondary battery to be different between the plurality of measurement modes, it becomes possible to make the measurement accuracy and the electric current consumption of the secondary battery different between the plurality of measurement modes. Moreover, by comparing the correlating parameter with the threshold value, it becomes possible to switch the measurement mode to a proper one of the plurality of measurement modes differing in waveform of the alternating current caused by the current generation unit to be outputted from the secondary battery.

According to a seventh solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, magnitude of the alternating current caused by the current generation unit to be outputted from the secondary battery.

With the above configuration, by setting the magnitude of the alternating current caused by the current generation unit to be outputted from the secondary battery to be different between the plurality of measurement modes, it becomes possible to make the measurement accuracy and the electric current consumption of the secondary battery different between the plurality of measurement modes. Moreover, by comparing the correlating parameter with the threshold value, it becomes possible to switch the measurement mode to a proper one of the plurality of measurement modes differing in magnitude of the alternating current caused by the current generation unit to be outputted from the secondary battery.

According to an eighth solution, the measurement unit includes: a current generation unit configured to cause alternating current to be outputted from the secondary battery; and a voltage measurement unit configured to measure a voltage of the secondary battery responding to the alternating current. The plurality of measurement modes differ in, as the measurement condition, manner of correcting the voltage of the secondary battery measured by the voltage measurement unit.

With the above configuration, by setting the manner of correcting the voltage of the secondary battery measured by the voltage measurement unit to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in manner of correcting the voltage of the secondary battery measured by the voltage measurement unit.

According to a ninth solution, the plurality of measurement modes differ in, as the measurement condition, temperature at which the impedance of the secondary battery is measured by the measurement unit.

With the above configuration, by setting the temperature at which the impedance of the secondary battery is measured by the measurement unit to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in temperature at which the impedance of the secondary battery is measured by the measurement unit.

According to a tenth solution, the secondary battery includes a plurality of battery cells. The measurement unit includes: current generation units configured to cause alternating currents to be outputted from the respective battery cells; and voltage measurement units configured to measure voltages of the secondary battery responding to the respective alternating currents. The plurality of measurement modes differ in, as the measurement condition, number of the current generation units and the voltage measurement units operated simultaneously.

With the above configuration, by setting the number of the current generation units and the voltage measurement units operated simultaneously to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in number of the current generation units and the voltage measurement units operated simultaneously.

The measurement time and the electric current consumption of the secondary battery vary depending on the number of battery cells on which the impedance measurement is performed. In this regard, according to an eleventh solution, the secondary battery includes a plurality of battery cells. The plurality of measurement modes differ in, as the measurement condition, number of the battery cells on which impedance measurement is performed. Moreover, the switching unit is configured to switch between the plurality of measurement modes based on a comparison between a correlating parameter, which correlates with the impedance of the secondary battery, and a threshold value. Consequently, by comparing the correlating parameter with the threshold value, it becomes possible to switch the measurement mode to a proper one of the plurality of measurement modes differing in number of the battery cells on which impedance measurement is performed.

According to a twelfth solution, in the second solution, the secondary battery includes a plurality of battery cells. The plurality of measurement modes further differ in, as the measurement condition, number of the battery cells on which impedance measurement is performed.

With the above configuration, the plurality of measurement modes differ in, as the measurement condition, both method of measuring the impedance by the measurement unit and number of the battery cells on which impedance measurement is performed. Consequently, by comparing the correlating parameter with the threshold value, it becomes possible to switch the measurement mode to a proper one of the plurality of measurement modes differing in both method of measuring the impedance by the measurement unit and number of the battery cells on which impedance measurement is performed.

According to a thirteenth solution, the plurality of measurement modes include: a first measurement mode in which the impedance measurement is performed on at least one predetermined battery cell among the plurality of battery cells; and a second measurement mode in which the impedance measurement is performed on more battery cells than the at least one predetermined battery cell among the plurality of battery cells.

With the above configuration, it becomes possible to make the measurement accuracy, the measurement time and the electric current consumption of the secondary battery different between the first measurement mode in which the impedance measurement is performed on at least one predetermined battery cell and the second measurement mode in which the impedance measurement is performed on more battery cells than the at least one predetermined battery cell. Consequently, by comparing the correlating parameter with the threshold value, it becomes possible to switch the measurement mode to a proper one of the first and second measurement modes. It should be noted that the at least one predetermined battery cell may be a single predetermined battery cell or a plurality of predetermined battery cells.

Among the plurality of battery cells, the battery cell(s) whose temperature is highest or lowest is more prone to deterioration than the other battery cells. In this regard, according to a fourteenth solution, the at least one predetermined battery cell is at least one battery cell whose temperature is highest or lowest among the plurality of battery cells. With such a configuration, it becomes possible to measure the impedance of the at least one predetermined battery cell, which is prone to deterioration, in the first measurement mode in which the number of battery cells on which the impedance measurement is performed is smaller than that in the second measurement mode. Thus, even with the smaller number of battery cells on which the impedance measurement is performed in the first measurement mode, it still becomes possible to suppress decrease in the accuracy of monitoring deterioration of the secondary battery.

Among the plurality of battery cells, the battery cell(s) whose temperature change is greatest is more prone to deterioration than the other battery cells. In this regard, according to a fifteenth solution, the at least one predetermined battery cell is at least one battery cell whose temperature change is greatest among the plurality of battery cells. With such a configuration, even with the smaller number of battery cells on which the impedance measurement is performed in the first measurement mode, it still becomes possible to suppress decrease in the accuracy of monitoring deterioration of the secondary battery.

Among the plurality of battery cells, the battery cell(s) on which an equalization process has been performed a greatest number of times may have been more deteriorated than the other battery cells. Otherwise, the battery cell(s) on which an equalization process has been performed a least number of times may have been more deteriorated and thus reduced in full-charge capacity by more than the other battery cells. In this regard, according to a sixteenth solution, an equalization process is performed to equalize residual capacities of the plurality of battery cells. The at least one predetermined battery cell is at least one battery cell on which the equalization process has been performed a greatest number of times or a least number of times among the plurality of battery cells. With such a configuration, even with the smaller number of battery cells on which the impedance measurement is performed in the first measurement mode, it still becomes possible to suppress decrease in the accuracy of monitoring deterioration of the secondary battery.

Among the plurality of battery cells, the battery cell(s) whose voltage change is greatest may be more prone to deterioration than the other battery cells. In this regard, according to a seventeenth solution, the at least one predetermined battery cell is at least one battery cell whose voltage change is greatest among the plurality of battery cells. With such a configuration, even with the smaller number of battery cells on which the impedance measurement is performed in the first measurement mode, it still becomes possible to suppress decrease in the accuracy of monitoring deterioration of the secondary battery.

Among the plurality of battery cells, the battery cell(s) whose resistance is highest may have been more deteriorated than the other battery cells. In this regard, according to an eighteenth solution, the at least one predetermined battery cell is at least one battery cell whose resistance is highest among the plurality of battery cells. With such a configuration, even with the smaller number of battery cells on which the impedance measurement is performed in the first measurement mode, it still becomes possible to suppress decrease in the accuracy of monitoring deterioration of the secondary battery.

Among the plurality of battery cells, the battery cell which is located at a predetermined position may have been more deteriorated than the other battery cells. In this regard, according to a nineteenth solution, the at least one predetermined battery cell is at least one battery cell which is located at a predetermined position among the plurality of battery cells. With such a configuration, even with the smaller number of battery cells on which the impedance measurement is performed in the first measurement mode, it still becomes possible to suppress decrease in the accuracy of monitoring deterioration of the secondary battery.

The measurement time and the electric current consumption of the secondary battery vary depending on the quantity of data acquired during the measurement of the impedance. In this regard, according to a twentieth solution, the plurality of measurement modes differ in, as the measurement condition, quantity of data acquired during measurement of the impedance. Moreover, the switching unit is configured to switch between the plurality of measurement modes based on a comparison between a correlating parameter, which correlates with the impedance of the secondary battery, and a threshold value. Consequently, by comparing the correlating parameter with the threshold value, it becomes possible to switch the measurement mode to a proper one of the plurality of measurement modes differing in quantity of data acquired during measurement of the impedance.

According to a twenty-first solution, in the second solution, the plurality of measurement modes further differ in, as the measurement condition, quantity of data acquired during measurement of the impedance.

With the above configuration, the plurality of measurement modes differ in, as the measurement condition, both method of measuring the impedance by the measurement unit and quantity of data acquired during measurement of the impedance. Consequently, by comparing the correlating parameter with the threshold value, it becomes possible to switch the measurement mode to a proper one of the plurality of measurement modes differing in both method of measuring the impedance by the measurement unit and quantity of data acquired during measurement of the impedance.

According to a twenty-second solution, in the eleventh solution, the plurality of measurement modes further differ in, as the measurement condition, quantity of data acquired during measurement of the impedance.

With the above configuration, the plurality of measurement modes differ in, as the measurement condition, both number of the battery cells on which impedance measurement is performed and quantity of data acquired during measurement of the impedance. Consequently, by comparing the correlating parameter with the threshold value, it becomes possible to switch the measurement mode to a proper one of the plurality of measurement modes differing in both number of the battery cells on which impedance measurement is performed and quantity of data acquired during measurement of the impedance.

According to a twenty-third solution, in the twelfth solution, the plurality of measurement modes further differ in, as the measurement condition, quantity of data acquired during measurement of the impedance.

With the above configuration, the plurality of measurement modes differ in, as the measurement condition, method of measuring the impedance by the measurement unit, number of the battery cells on which impedance measurement is performed and quantity of data acquired during measurement of the impedance. Consequently, by comparing the correlating parameter with the threshold value, it becomes possible to switch the measurement mode to a proper one of the plurality of measurement modes differing in method of measuring the impedance by the measurement unit, number of the battery cells on which impedance measurement is performed and quantity of data acquired during measurement of the impedance.

According to a twenty-fourth solution, the plurality of measurement modes include: a first measurement mode in which the impedance is measured with respect to at least one predetermined frequency; and a second measurement mode in which the impedance is measured with respect to more frequencies than the at least one predetermined frequency.

With the above configuration, it becomes possible to make the measurement accuracy, the measurement time and the electric current consumption of the secondary battery different between the first measurement mode in which the impedance is measured with respect to at least one predetermined frequency and the second measurement mode in which the impedance is measured with respect to more frequencies than the at least one predetermined frequency. Consequently, by comparing the correlating parameter with the threshold value, it becomes possible to switch the measurement mode to a proper one of the first and second measurement modes. It should be noted that the at least one predetermined frequency may be a single predetermined frequency or a plurality of predetermined frequencies.

According to a twenty-fifth solution, in the twenty-fourth solution, the switching unit is configured to: switch the measurement mode to the first measurement mode when the secondary battery is not determined to be abnormal; and switch the measurement mode to the second measurement mode when the secondary battery is determined in the first measurement mode to be abnormal. With such a configuration, when the secondary battery is determined in the first measurement mode to be abnormal, it will be possible to switch the measurement mode to the second measurement mode in which the impedance of the secondary battery is measured with respect to more frequencies, thereby improving the measurement accuracy. On the other hand, when the secondary battery is not determined to be abnormal, it will be possible to measure the impedance of the secondary battery with respect to fewer frequencies in the first measurement mode, thereby shortening the measurement time and reducing the electric current consumption of the secondary battery.

According to a twenty-sixth solution, in the second measurement mode, the impedance is measured with respect to frequencies within a measurement range depending on content of abnormality. With such a configuration, it becomes possible to set, according to the content of abnormality, the range of frequencies for measuring the impedance in the second measurement mode, thereby facilitating ascertainment of the cause of the abnormality.

According to a twenty-seventh solution, in the second measurement mode, a frequency at which the impedance satisfies a predetermined condition is searched. With such a configuration, when the secondary battery is determined to be abnormal, it will be possible to ascertain the frequency at which the impedance satisfies the predetermined condition.

The characteristics of the secondary battery can be predicted to some extent based on a correlating parameter other than the impedance. In this regard, according to a twenty-eighth solution, the at least one predetermined frequency is at least one frequency set based on the correlating parameter other than the impedance. With such a configuration, the at least one predetermined frequency can be properly set upon predication of the characteristics of the secondary battery; consequently, decrease in the measurement accuracy can be suppressed even in the first measurement mode in which the quantity of data acquired during the measurement of the impedance is smaller than that in the second measurement mode.

The impedance measurement condition suitable for ascertaining the characteristics of the secondary battery changes depending on the state of the secondary battery. Moreover, the state of the secondary battery can be estimated based on the impedance. In this regard, according to a twenty-ninth solution, the at least one predetermined frequency is at least one frequency set based on the state of the secondary battery estimated based on the impedance. With such a configuration, the at least one predetermined frequency in the first measurement mode can be properly set upon estimation of the state of the secondary battery based on the impedance. Consequently, decrease in the measurement accuracy can be suppressed even in the first measurement mode in which the quantity of data acquired during the measurement of the impedance is smaller than that in the second measurement mode.

According to a thirtieth solution, the plurality of measurement modes include: a first measurement mode in which the impedance is measured at a predetermined period; and a second measurement mode in which the impedance is measured at a period shorter than the predetermined period.

With the above configuration, it becomes possible to make the measurement accuracy, the measurement time and the electric current consumption of the secondary battery different between the first measurement mode in which the impedance is measured at a predetermined period and the second measurement mode in which the impedance is measured at a period shorter than the predetermined period. Moreover, by comparing the correlating parameter with the threshold value, it becomes possible to switch the measurement mode to a proper one of the first and second measurement modes.

According to a thirty-first solution, the at least one predetermined frequency is at least one frequency at which the impedance satisfies a predetermined condition. With such a configuration, it becomes possible to measure, in the first measurement mode, the impedance with respect to the at least one frequency at which the impedance satisfies the predetermined condition. Moreover, it becomes easier to ascertain the characteristics of the secondary battery even in the first measurement mode in which the quantity of data acquired during the measurement of the impedance is smaller than that in the second measurement mode.

According to a thirty-second solution, the switching unit is configured to switch between the plurality of measurement modes when the correlating parameter exceeds the threshold value. With such a configuration, it becomes possible to switch between the plurality of measurement modes in response to a change in the correlating parameter that correlates with the impedance of the secondary battery.

According to a thirty-third solution, the switching unit is further configured to switch between the plurality of measurement modes in response to a change in the relationship between the impedance and a characteristic of the secondary battery other than the impedance. With such a configuration, it becomes possible to switch between the plurality of measurement modes in response to a change in the characteristic of the secondary battery relating to the impedance.

According to a thirty-fourth solution, the switching unit is further configured to switch between the plurality of measurement modes according to a state of a surrounding environment of the secondary battery. With such a configuration, even when there is a change in the state of the surrounding environment of the secondary battery, it will still be possible to switch the measurement mode to a proper one of the plurality of measurement modes.

According to a thirty-fifth solution, the switching unit is further configured to switch between the plurality of measurement modes based on a predetermined schedule. With such a configuration, it becomes possible to switch between the plurality of measurement modes based on the predetermined schedule regardless of the state of the secondary battery.

The characteristics of the secondary battery change depending on the usage history of the secondary battery. In this regard, according to a thirty-sixth solution, the switching unit is further configured to switch between the plurality of measurement modes based on the usage history of the secondary battery. With such a configuration, it becomes possible to switch, taking into account the usage history of the secondary battery, the measurement mode to a proper one of the plurality of measurement modes.

According to a thirty-seventh solution, the switching unit is capable of changing, based on predetermined information, condition for switching between the plurality of measurement modes. With such a configuration, the condition for switching the measurement mode can be changed based on the predetermined information, rather than being fixed.

According to a thirty-eighth solution, the measurement unit includes a mode change unit configured to change, based on predetermined information, contents of the plurality of measurement modes. With such a configuration, the contents of the plurality of measurement modes can be changed based on the predetermined information, rather than being fixed.

According to a thirty-ninth solution, the predetermined information is information on the usage history of the secondary battery. With such a configuration, it becomes possible to suitably change, taking into account the usage history of the secondary battery, the condition for switching between the plurality of measurement modes and/or the contents of the plurality of measurement modes.

According to a fortieth solution, the predetermined information is acquired from outside the impedance measurement apparatus through communication. With such a configuration, it becomes possible to suitably change, taking into account the predetermined information acquired from outside the impedance measurement apparatus through communication, the condition for switching between the plurality of measurement modes and/or the contents of the plurality of measurement modes.

According to a forty-first solution, the predetermined information is stored in an external server connected with the impedance measurement apparatus via the Internet. With such a configuration, it becomes possible to acquire the predetermined information from the external server connected with the impedance measurement apparatus via the Internet.

Specifically, as a forty-second solution, a configuration may be employed where the predetermined information is acquired only when the impedance measurement apparatus is electrically connected externally.

### BRIEF DESCRIPTION OF THE DRAWINGS

FIG. 1 is an electric circuit diagram of an electric power supply system.

FIG. 2 is a block diagram of a battery measurement unit and a battery control ECU.

FIG. 3 is a time chart illustrating a manner of measurement mode switching.

FIG. 4 is a diagram illustrating measurement modes according to a first embodiment.

FIG. 5 is a diagram illustrating the relationship between temperature, alternating current frequency and lithium precipitation.

FIG. 6 is a schematic diagram illustrating measurement modes according to a second embodiment.

FIG. 7 is a schematic diagram illustrating measurement modes according to a third embodiment.

FIG. 8 is a block diagram illustrating a modification of the battery measurement unit.

FIG. 9 is a block diagram illustrating another modification of the battery measurement unit.

FIG. 10 is a block diagram illustrating another modification of the battery measurement unit.

FIG. 11 is a block diagram illustrating another modification of the battery measurement unit.

### DESCRIPTION OF EMBODIMENTS

### First Embodiment

Hereinafter, a first embodiment will be described with reference to the drawings; in the first embodiment, an “impedance measurement apparatus for a secondary battery” is applied to an electric power supply system of a vehicle (e.g., a hybrid vehicle or an electric vehicle).

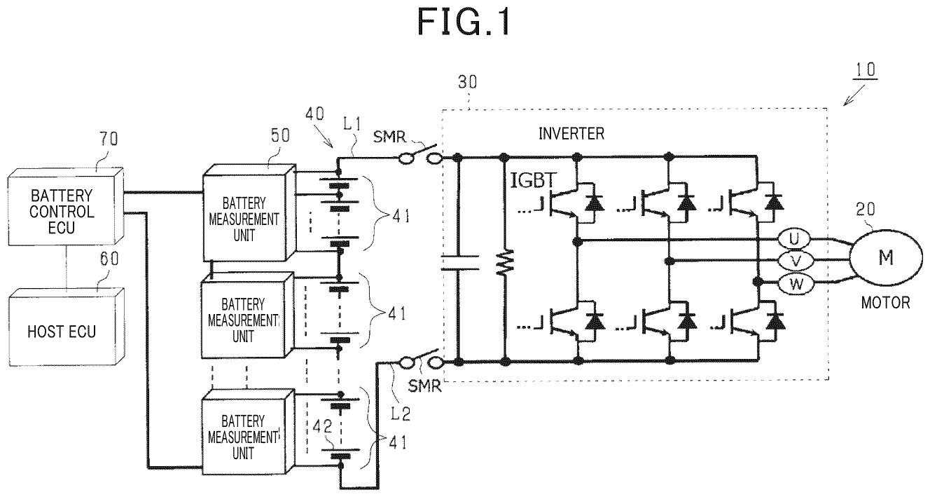

As shown in FIG. 1, the electric power supply system 10 includes a motor 20 that is a rotating electric machine, an inverter 30 that functions as an electric power converter to supply three-phase alternating current to the motor 20, a rechargeable battery pack 40, battery measurement units 50 that measure a state of the battery pack 40, a battery control ECU 70 that controls the battery pack 40, and a host ECU 60 that controls the motor 20 and the like.

The motor 20 is an in-vehicle main machine. The motor 20 is configured so that mechanical power can be transmitted between the motor 20 and drive wheels (not shown) of the vehicle. In the present embodiment, the motor 20 is implemented by a three-phase permanent magnet synchronous motor. The inverter 30 is configured with a full bridge circuit having a plurality of pairs of upper and lower arms. The number of pairs of the upper and lower arms is equal to the number of phases of phase windings of the motor 20. Each of the upper and lower arms has a switch (or semiconductor switching element) provided therein; electric current supplied to the phase windings of the motor 20 is controlled by turning on/off the switches of the upper and lower arms.

Specifically, an inverter control device (not shown) is provided in the inverter 30. The inverter control device controls, based on various types of information detected in the motor 20 and a power running drive request or an electric power generation request, the on/off of the switches in the inverter 30, thereby controlling energization of the phase windings of the motor 20. More specifically, the inverter control device controls the supply of electric power from the battery pack 40 to the motor 20 via the inverter 30, thereby driving the motor 20 to operate in a power running mode. Otherwise, when the motor 20 operates in an electric power generation mode in which the motor 20 is driven by mechanical power transmitted from the drive wheels of the vehicle to generate three-phase AC power, the inverter control device controls the inverter 30 to convert the three-phase AC power generated by the motor 20 into a DC power; the DC power is then supplied to the battery pack 40 to charge it.

The battery pack 40 is electrically connected with the motor 20 via the inverter 30. The battery pack 40 has an inter-terminal voltage higher than or equal to, for example 100V. The battery pack 40 is constituted of a plurality of battery modules 41 that are connected in series with each other. Moreover, each of the battery modules 41 is constituted of a plurality of battery cells 42 that are connected in series with each other. The battery cells 42 (each corresponding to a secondary battery) may be implemented by, for example, lithium iron phosphate batteries (i.e., LFP batteries), lithium-ion batteries or nickel-metal hydride batteries. That is, each of the battery cells 42 is a storage battery which includes an electrolyte and a plurality of electrodes.

As shown in FIG. 1, to a positive-electrode-side electric power supply path L1 that is connected with a positive-electrode-side electric power supply terminal of the battery pack 40, there are connected positive-electrode-side terminals of electrical loads such as the inverter 30. On the other hand, to a negative-electrode-side electric power supply path L2 that is connected with a negative-electrode-side electric power supply terminal of the battery pack 40, there are connected negative-electrode-side terminals of the electrical loads. Moreover, in each of the positive-electrode-side and negative-electrode-side electric power supply paths L1 and L2, there is provided an SMR (i.e., system main relay) switch to selectively allow and interrupt flow of electric current through the electric power supply path.

The battery measurement units 50 (each corresponding to a measurement unit) are provided to measure the SOC (i.e., state of charge) and SOH (i.e., state of health) of each of the battery cells 42. The battery measurement units 50 are connected with the battery control ECU 70. The battery measurement units 50 measure the impedances of the battery cells 42 and output the measured impedances to the battery control ECU 70. Moreover, the battery measurement units 50 are capable of measuring the impedances of the battery cells 42 using a plurality of measurement modes differing in measurement condition. The configuration of the battery measurement units 50 will be described in detail later.

The battery control ECU 70 (corresponding to a switching unit) controls the battery measurement units 50 to measure the impedances of the battery cells 42 in a selected one of the measurement modes. The battery control ECU 70 switches (or selects) between the measurement modes on the basis of a comparison between a correlating parameter, which correlates with impedance, and a threshold value. In addition, each battery measurement unit 50 and the battery control ECU 70 together constitute an impedance measurement apparatus for a secondary battery.

The host ECU 60 makes, based on various types of information, either the power running drive request or the electric power generation request to the inverter control device. The various types of information may include, for example, accelerator operation information, brake operation information, the vehicle speed and the state of the battery pack 40. Moreover, the results of measuring the states of the battery cells 42 are inputted from the battery control ECU 70 to the host ECU 60.

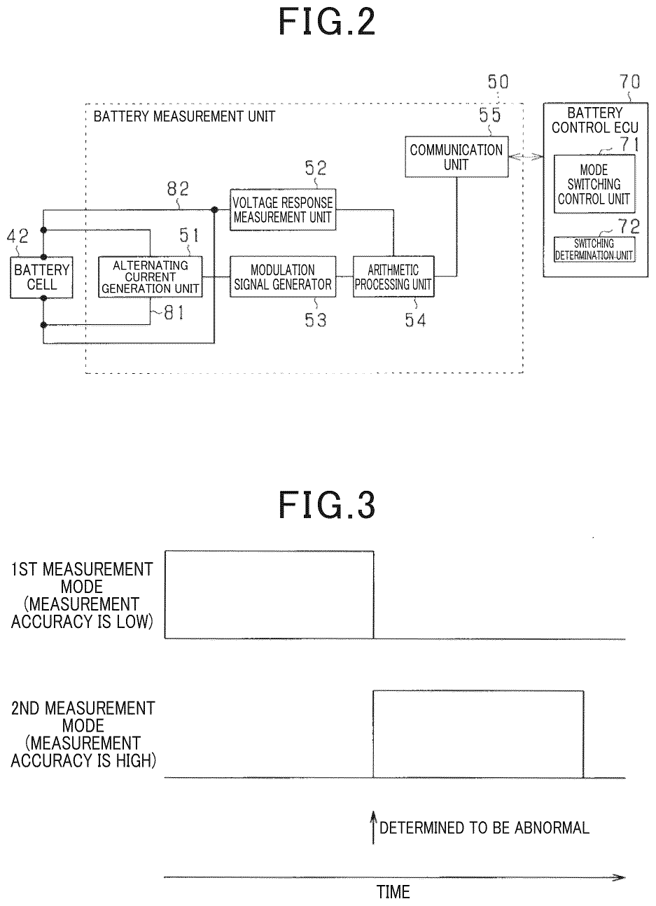

Next, the battery measurement units 50 and the battery control ECU 70 will be described in detail. As shown in FIG. 2, each of the battery measurement units 50 is provided so as to be capable of measuring the state of each corresponding battery cell 42. Specifically, each of the battery measurement units 50 includes an alternating current generation unit 51 connected with each corresponding battery cell 42 via a first electrical path 81, a voltage response measurement unit 52 connected with each corresponding battery cell 42 via a second electrical path 82, a modulation signal generator 53 connected with the alternating current generation unit 51, an arithmetic processing unit 54 connected with both the voltage response measurement unit 52 and the modulation signal generator 53, and a communication unit 55 connected with the arithmetic processing unit 54.

The alternating current generation unit 51 (corresponding to a current generation unit) causes alternating current to be outputted with the battery cell 42, which is the measurement target, being an electric power source for the output of the alternating current. More specifically, the alternating current generation unit 51 causes, based on a command signal inputted from the modulation signal generator 53, alternating current to be outputted from the battery cell 42. With the alternating current flowing from the battery cell 42, a response signal (i.e., voltage variation) that reflects information on the complex impedance (corresponding to impedance) is generated in the inter-terminal voltage of the battery cell 42. The voltage response measurement unit 52 (corresponding to a voltage measurement unit) measures the response signal (i.e., voltage variation), which reflects information on the complex impedance of the battery cell 42, between the terminals of the battery cell 42.

The modulation signal generator 53 includes an oscillator that generates an AC signal with an arbitrary waveform. Moreover, the modulation signal generator 53 causes, according to instructions from the arithmetic processing unit 54, the oscillator to generate the AC signal.

In the present embodiment, the AC signal is a sine-wave signal. However, the AC signal may be changed arbitrarily. For example, the AC signal may alternatively be a rectangular-wave signal, a triangular-wave signal or the like. Moreover, a DC bias is applied to the AC signal so that the alternating current flowing from the battery cell 42 never becomes negative current (or reverse current to the battery cell 42).

Furthermore, the modulation signal generator 53 generates the command signal by converting the AC signal into a digital signal, and commands the alternating current generation unit 51 to cause, based on the command signal, alternating current to be generated.

The arithmetic processing unit 54 is configured with a microcomputer which includes a CPU (or a calculation device) and a storage device (or various memories). The arithmetic processing unit 54 realizes various functions by executing programs stored in the storage device. It should be noted that the various functions may alternatively be realized by electronic circuits that are hardware, or be realized by both hardware and software.

The arithmetic processing unit 54 has a function of calculating the complex impedance of the battery cell 42. Hereinafter, an outline of a method for calculating the complex impedance will be described. The arithmetic processing unit 54 instructs the modulation signal generator 53 on the measurement frequencies of the complex impedance. Based on the instructions from the arithmetic processing unit 54, the modulation signal generator 53 causes, via the alternating current generation unit 51, alternating current to be generated from the battery cell 42. The voltage response measurement unit 52 measures, by measuring the inter-terminal voltage of the battery cell 42, the response signal (i.e., voltage variation) responding to the alternating current and outputs the measured response signal to the arithmetic processing unit 54.

The arithmetic processing unit 54 calculates, based on the response signal, information on the complex impedance of the battery cell 42. The arithmetic processing unit 54 repeats this series of processes until the complex impedance is calculated with respect to a plurality of measurement frequencies predetermined within a measurement range. Moreover, the arithmetic processing unit 54 informs the battery control ECU 70 of the calculation results. Based on the calculation results, the battery control ECU 70 creates a complex impedance plane plot (e.g., Cole-Cole plot) and ascertains the characteristics of the electrodes, electrolyte, etc. of the battery cell 42. In addition, the battery control ECU 70 determines the state of charge (SOC) and state of health (SOH) of the battery cell 42.

In addition, it is not necessary to create the entire Cole-Cole plot; rather, it is possible to focus on only part of it. For example, during traveling of the vehicle, it is possible to: measure the complex impedance with respect to a specific frequency at regular time intervals; and determine, based on the change with time of the complex impedance with respect to the specific frequency, the changes in the SOC, the SOH, the battery temperature and the like during the traveling. Alternatively, it is possible to: measure the complex impedance with respect to the specific frequency at time intervals such as once every day, once every week or once every year; and determine, based on the change with time of the complex impedance with respect to the specific frequency, the changes in the SOH and the like. Moreover, the complex impedance plane plot is not limited to the Cole-Cole plot, but a Bode plot or the like may alternatively be created.

In order to ensure the measurement accuracy of the complex impedance, it is necessary to suppress errors by averaging (or integrating) the measured values of the voltage variation; it is also necessary to output a certain number of wave cycles of each AC signal at each measurement frequency and measure the voltage variation for the duration of the output. That is, when the required accuracy is predetermined, it is necessary to output a required number, which depends on the required accuracy, of wave cycles of the AC signal. Moreover, if the measurement frequency differs, the number of wave cycles per unit time also differs. Therefore, it is necessary to output the alternating current for a longer duration when the measurement frequency is low than when the measurement frequency is high. In other words, the required output duration differs for each measurement frequency.

In view of the above, in the present embodiment, as shown in FIG. 3, the battery control ECU 70 normally measures the complex impedance in a first measurement mode with lower measurement accuracy. When it is determined, based on the measurement results, that the battery cell 42 is abnormal, the battery control ECU 70 switches the measurement mode from the first measurement mode to the second measurement mode and measures the complex impedance in the second measurement mode; the measurement accuracy is higher in the second measurement mode than in the first measurement mode. That is, the battery control ECU 70 normally measures the complex impedance (or correlating parameter) in the first measurement mode with lower measurement accuracy; when the battery cell 42 is determined to be abnormal, the battery control ECU 70 measures the complex impedance in the second measurement mode with higher measurement accuracy. The timing for measuring the complex impedance in the first measurement mode may be set arbitrarily. Moreover, the complex impedance may be measured in the second measurement mode immediately after the battery cell 42 is determined in the first measurement mode to be abnormal; alternatively, it may be measured in the second measurement mode after a predetermined time from when the battery cell 42 is determined in the first measurement mode to be abnormal.

In the present embodiment, as shown in FIG. 2, the battery control ECU 70 includes a mode switching control unit 71 and a switching determination unit 72. The switching determination unit 72 determines the battery cell 42 to be normal when the complex impedance of the battery cell 42 measured in the first measurement mode is within a normal range, and to be abnormal when the complex impedance of the battery cell 42 measured in the first measurement mode is out of the normal range (e.g., greater than a threshold value or less than a threshold value). The mode switching control unit 71 commands, via the communication unit 55, the arithmetic processing unit 54 to switch the measurement mode to the first measurement mode when the battery cell 42 is determined to be normal and to the second measurement mode when the battery cell 42 is determined to be abnormal.

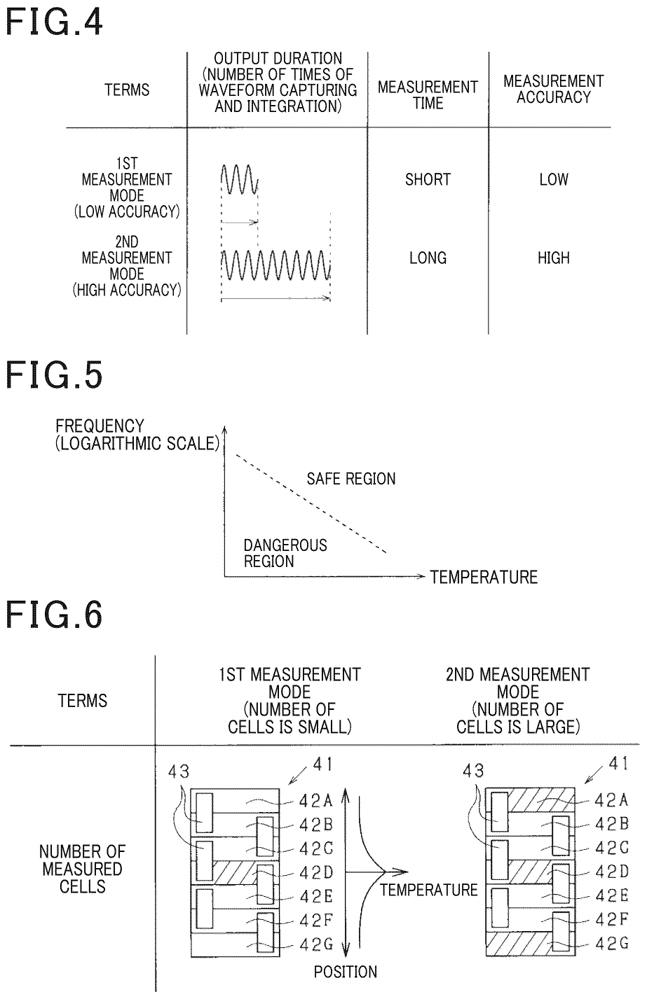

Specifically, the arithmetic processing unit 54 determines an output duration of the AC signal on the basis of the set measurement frequency. The output duration, which is the duration required for a predetermined number of wave cycles of the AC signal to be outputted, is calculated based on the measurement frequency. The predetermined number is set in advance according to the required measurement accuracy. For example, as shown in FIG. 4, the predetermined number may be set to be 3 in the first measurement mode and to be 9 in the second measurement mode. That is, the predetermined number is set to be greater in the second measurement mode than in the first measurement mode. Hence, the number of times of causing, by the alternating current generation unit 51, alternating current to be outputted from the battery cell 42 and measuring the voltage of the battery cell 42 by the voltage response measurement unit 52 differs between the first measurement mode and the second measurement mode. That is, the method of measuring the complex impedance differs between the first measurement mode and the second measurement mode. Therefore, the measurement time is longer in the second measurement mode than in the first measurement mode. Moreover, the measurement accuracy is higher in the second measurement mode than in the first measurement mode.

Next, the arithmetic processing unit 54 instructs the modulation signal generator 53 of the set measurement frequency. Further, in the modulation signal generator 53, the frequency of the AC signal to be outputted by the oscillator is set according to the instructed measurement frequency. Then, the oscillator of the modulation signal generator 53 generates the AC signal with the set measurement frequency. Thereafter, the modulation signal generator 53 generates, by converting the AC signal that is an analog signal into a digital signal, the command signal for causing alternating current to be outputted from the battery cell 42 and outputs the generated command signal to the alternating current generation unit 51.

The alternating current generation unit 51 causes, based on the command signal, alternating current to be outputted from the battery cell 42. The voltage response measurement unit 52 measures, by measuring the inter-terminal voltage of the battery cell 42, the response signal (i.e., voltage variation) responding to the alternating current. Further, the voltage response measurement unit 52 converts the measured response signal that is an analog signal into a digital value and outputs the digital value to the arithmetic processing unit 54.

The arithmetic processing unit 54 calculates, based on the alternating current and the voltage variation, information on the complex impedance of the battery cell 42. Specifically, the arithmetic processing unit 54 acquires measured values of the alternating current. More specifically, the alternating current flowing through the first electrical path 81 is measured. The measured alternating current is then analyzed according to the frequency (i.e., measurement frequency) of each AC signal; and each AC signal (measurement signal) that actually flowed is extracted and acquired.

Moreover, the arithmetic processing unit 54 analyzes the response signal on the basis of the acquired AC signal, and calculates both a value proportional to the real part of the response signal and a value proportional to the imaginary part of the response signal (i.e., calculates information on the complex impedance). In addition, each of the value proportional to the real part of the response signal and the value proportional to the imaginary part of the response signal is an average value (or integral value) from the start of output of each AC signal.

Next, the arithmetic processing unit 54 determines whether the output duration of the AC signal corresponding to each measurement mode has ended. In the first measurement mode, the output duration is the duration until three wave cycles of the AC signal are outputted. In contrast, in the second measurement mode, the output duration is the duration until nine wave cycles of the AC signal are outputted. When the result of the determination is negative, the arithmetic processing unit 54 continues the measurement and calculation. In contrast, when the result of the determination is positive, the arithmetic processing unit 54 stops the generation of the AC signal.

The arithmetic processing unit 54 acquires the values respectively proportional to the real and imaginary parts of the response signal corresponding to the AC signal. Then, based on the acquired values, the arithmetic processing unit 54 calculates both or either of the absolute value and phase of the complex impedance at the measurement frequency of the AC signal. Thereafter, the arithmetic processing unit 54 informs the battery control ECU 70 of the calculated complex impedance.

According to the present embodiment, it is possible to achieve the following advantageous effects.

The inventors of the present application have focused on the fact that there exist correlating parameters (including the impedance itself) that correlate with the impedance and the measurement mode to be selected can be determined based on the correlating parameters. Hence, in the present embodiment, the battery control ECU 70 switches the measurement mode based on a comparison between a correlating parameter, which correlates with the impedance, and a threshold value. Consequently, by comparing the correlating parameter with the threshold value, it becomes possible to switch the measurement mode to a proper measurement mode. Specifically, when the complex impedance of the battery cell 42 measured in the first measurement mode is out of a normal range (e.g., greater than a threshold value or less than a threshold value), the switching determination unit 72 determines that the battery cell 42 is abnormal. Moreover, when the battery cell 42 is determined to be abnormal, the mode switching control unit 71 commands the arithmetic processing unit 54 to switch the measurement to the second measurement mode. Consequently, it becomes possible to shorten the measurement time and reduce the electric current consumption of the battery cell 42 in comparison with the case of performing the measurement in a single measurement mode regardless of the correlating parameter.

The first and second measurement modes differ in, as the measurement condition, method of measuring the impedance by the battery measurement unit 50. The battery control ECU 70 switches the measurement mode based on a comparison between a correlating parameter, which correlates with the impedance, and a threshold value. Consequently, by comparing the correlating parameter with the threshold value, it becomes possible to switch the measurement mode to a proper one of the first and second measurement modes differing in method of measuring the impedance.

By setting the number of times of causing alternating current to be outputted from the battery cell 42 and measuring the voltage of the battery cell 42 to be different between the first and second measurement modes, it becomes possible to make the measurement accuracy, the measurement time and the electric current consumption of the battery cell 42 different between the first and second measurement modes. Moreover, by comparing the correlating parameter with the threshold value, it becomes possible to switch the measurement mode to a proper one of the first and second measurement modes differing in number of times of causing alternating current to be outputted from the battery cell 42 and measuring the voltage of the battery cell 42.

The first embodiment may also be implemented through the following modifications. It should be noted that: parts in the following modifications identical to those in the first embodiment are designated by the same reference signs as those in the first embodiment; and description of these parts will be omitted.

A configuration may alternatively be employed where the plurality of measurement modes differ in, as the measurement condition, number of bits of the digital value obtained by the AD conversion of the analog value of the voltage of the battery cell 42 measured by the voltage response measurement unit 52. For example, the number of bits of the digital value may be set to be greater in the second measurement mode than in the first measurement mode. Moreover, the number of bits of the digital value may be varied by using a plurality of AD converters differing in number of bits obtained by the conversion, or be varied by software processing when converting the analog value into the digital value.

With the above configuration, by setting the number of bits of the digital value obtained by the AD conversion of the analog value of the voltage of the battery cell 42 measured by the voltage response measurement unit 52 to be different between the plurality of measurement modes, it becomes possible to make the measurement accuracy and the measurement time different between the plurality of measurement modes. Moreover, by comparing a correlating parameter (e.g., the complex impedance itself, the state of charge (SOC) of the battery cell 42, the state of health (SOH) of the battery cell 42, the temperature of the battery cell 42, or the like) with a threshold value, it becomes possible to switch the measurement mode to a proper one of the plurality of measurement modes differing in number of bits of the digital value obtained by the AD conversion of the analog value of the voltage of the battery cell 42. It should be noted that in the following embodiments and modifications as well, correlating parameters, which correlate with the impedance of the battery cell 42, include the complex impedance itself, the state of charge (SOC) of the battery cell 42, the state of health (SOH) of the battery cell 42, the temperature of the battery cell 42, etc.

For example, the measurement mode may be switched to the first measurement mode when the SOC of the battery cell 42 is out of a predetermined range (e.g., lower than a first threshold value or higher than a second threshold value) and to the second measurement mode when the SOC of the battery cell 42 is within the predetermined range (e.g., higher than the first threshold value and lower than the second threshold value). Alternatively, the measurement mode may be switched to the first measurement mode when the SOH of the battery cell 42 is higher than a threshold value and to the second measurement mode when the SOH of the battery cell 42 is lower than the threshold value. Alternatively, the measurement mode may be switched to the first measurement mode when the temperature of the battery cell 42 is lower than a threshold value and to the second measurement mode when the temperature of the battery cell 42 is higher than the threshold value. It should be noted that in the following embodiments and modifications as well, the measurement mode may be similarly switched between the first and second measurement modes according to the SOC, SOH or temperature of the battery cell 42.

The battery measurement unit 50 may include a low-pass filter to cut off those frequency components of the voltage of the battery cell 42 measured by the voltage response measurement unit 52 which are higher than a cutoff frequency. Moreover, a configuration may alternatively be employed where the plurality of measurement modes differ in, as the measurement condition, cutoff frequency of the low-pass filter. For example, the cutoff frequency may be set to lower in the second measurement mode than in the first measurement mode.

With the above configuration, by setting the cutoff frequency of the low-pass filter to be different between the plurality of measurement modes, it becomes possible to make the measurement accuracy and the measurement time different between the plurality of measurement modes. Moreover, by comparing a correlating parameter with a threshold value, it becomes possible to switch the measurement mode to a proper one of the plurality of measurement modes differing in cutoff frequency of the low-pass filter.

A configuration may alternatively be employed where the plurality of measurement modes differ in, as the measurement condition, waveform of the alternating current caused by the alternating current generation unit 51 to be outputted from the battery cell 42. For example, a rectangular waveform and a sinusoidal waveform may be used as the waveform of the alternating current.

With the above configuration, by setting the waveform of the alternating current caused by the alternating current generation unit 51 to be outputted from the battery cell 42 to be different between the plurality of measurement modes, it becomes possible to make the measurement accuracy and the electric current consumption of the battery cell 42 different between the plurality of measurement modes. Moreover, by comparing the correlating parameter with the threshold value, it becomes possible to switch the measurement mode to a proper one of the plurality of measurement modes differing in waveform of the alternating current caused by the alternating current generation unit 51 to be outputted from the battery cell 42.

A configuration may alternatively be employed where the plurality of measurement modes differ in, as the measurement condition, magnitude (or amplitude) of the alternating current caused by the alternating current generation unit 51 to be outputted from the battery cell 42. For example, the magnitude of the alternating current may be set to be higher in the second measurement mode than in the first measurement mode.

With the above configuration, by setting the magnitude of the alternating current caused by the alternating current generation unit 51 to be outputted from the battery cell 42 to be different between the plurality of measurement modes, it becomes possible to make the measurement accuracy and the electric current consumption of the battery cell 42 different between the plurality of measurement modes. Moreover, by comparing the correlating parameter with the threshold value, it becomes possible to switch the measurement mode to a proper one of the plurality of measurement modes differing in magnitude of the alternating current caused by the alternating current generation unit 51 to be outputted from the battery cell 42. For example, in the first measurement mode, the magnitude of the alternating current may set to be lower, thereby reducing the electric current consumption of the battery cell 42; in the second measurement mode, the magnitude of the alternating current may set to be higher, thereby improving the measurement accuracy.

A configuration may alternatively be employed where the plurality of measurement modes differ in, as the measurement condition, manner of correcting the voltage of the battery cell 42 measured by the voltage response measurement unit 52. For example, the execution/non-execution and accuracy of correction for the inter-terminal voltage of the battery cell 42 measured by the voltage response measurement unit 52 and the execution/non-execution and accuracy of correction against external influences, such as the magnetic influence of a bus bar (wiring), may be set to be different between the plurality of measurement modes. Moreover, when measuring the complex impedance with respect to a specific measurement frequency (or when ascertaining the tendency of change), the measurement mode may be switched to the first measurement mode in which no correction is executed. In contrast, when measuring the complex impedance with respect to a plurality of measurement frequencies (or when determining the value of the complex impedance with respect to each measurement frequency), the measurement mode may be switched to the second measurement mode in which correction is executed.

With the above configuration, by setting the manner of correcting the voltage of the battery cell 42 measured by the voltage response measurement unit 52 to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in manner of correcting the voltage of the battery cell 42 measured by the voltage response measurement unit 52.

The battery measurement unit 50 may include a cooling mechanism (e.g., a cooling fan or a cooling water circulation mechanism) that cools the battery cell 42 (or the battery module 41, the battery pack 40). Moreover, a configuration may alternatively be employed where the plurality of measurement modes differ in, as the measurement condition, temperature at which the impedance of the battery cell 42 is measured by the battery measurement unit 50. For example, the cooling mechanism may be turned off in the first measurement mode and turned on in the second measurement mode.

With the above configuration, by setting the temperature at which the impedance of the battery cell 42 is measured by the battery measurement unit 50 to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in temperature at which the impedance of the battery cell 42 is measured by the battery measurement unit 50.

A configuration may alternatively be employed where the plurality of measurement modes differ in, as the measurement condition, number of alternating current generation units 51 and voltage response measurement units 52 operated simultaneously. For example, the number of alternating current generation units 51 and voltage response measurement units 52 operated simultaneously may be set to be smaller in the second measurement mode than in the first measurement mode.

With the above configuration, by setting the number of alternating current generation units 51 and voltage response measurement units 52 operated simultaneously to be different between the plurality of measurement modes, it becomes possible to make the measurement accuracy and the measurement time different between the plurality of measurement modes. Moreover, by comparing the correlating parameter with the threshold value, it becomes possible to switch the measurement mode to a proper one of the plurality of measurement modes differing in number of alternating current generation units 51 and voltage response measurement units 52 operated simultaneously. For example, in the first measurement mode, the number of alternating current generation units 51 and voltage response measurement units 52 operated simultaneously may be set to be larger, thereby shortening the measurement time; in the second measurement mode, the number of alternating current generation units 51 and voltage response measurement units 52 operated simultaneously may be set to be smaller, thereby improving the measurement accuracy.

The inventors of the present application have focused on the fact that in a lithium-ion battery, when the battery cell 42 is charged or discharged in a region where the temperature is low and the frequency of the alternating current is low (i.e., a dangerous region) as shown in FIG. 5, it is easy for lithium to precipitate at the electrodes. In particular, the higher the amplitude of the alternating current is and the longer the duration for which the alternating current is caused to flow, the easier it is for lithium to precipitate. On the other hand, when the battery cell 42 is charged or discharged in a region where the temperature is high and the frequency of the alternating current is high (i.e., a safe region), it is difficult for lithium to precipitate at the electrodes.

Therefore, the battery control ECU 70 may cause the battery measurement unit 50 to measure the complex impedance of the battery cell 42 in the first measurement mode when the temperature of the battery cell 42 and the measurement frequency of the complex impedance are within the dangerous region, and cause the battery measurement unit 50 to measure the complex impedance of the battery cell 42 in the second measurement mode when the temperature of the battery cell 42 and the measurement frequency of the complex impedance are within the safe region. Moreover, the amplitude of the alternating current is lower and the duration for which the alternating current is caused to flow is shorter in the first measurement mode than in the second measurement mode. With such a configuration, it becomes possible to suppress precipitation of lithium at the electrodes of the battery cell 42 even in the case of measuring the complex impedance of the battery cell 42 in the dangerous region.

### Second Embodiment

Hereinafter, a second embodiment will be described with reference to the drawings, focusing on the differences thereof from the first embodiment. It should be noted that: parts in the second embodiment identical to those in the first embodiment are designated by the same reference signs as those in the first embodiment; and description of these parts will be omitted.

In the present embodiment, as shown in FIG. 6, each battery module 41 includes a plurality of battery cells 42A to 42G as the battery cells 42. All the battery cells 42 are stacked together and connected in series with each other by bus bars 43. Moreover, of the battery cells 42, the battery cells 42A and 42G are end battery cells 42 located respectively at two ends of the battery module 41, while the battery cell 42D is a central battery cell 42 located at the center of the battery module 41.

The measurement time and the electric current consumption of a secondary battery vary depending on the number of the battery cells 42 on which the impedance measurement is performed. In this regard, in the present embodiment, the plurality of measurement modes differ in, as the measurement condition, number of the battery cells 42 on which the impedance measurement is performed. Moreover, the battery control ECU 70 switches the measurement mode between the plurality of measurement modes based on a comparison between a correlating parameter, which correlates with the impedance, and a threshold value. Consequently, by comparing the correlating parameter with the threshold value, it becomes possible to switch the measurement mode to a proper one of the plurality of measurement modes differing in number of the battery cells 42 on which the impedance measurement is performed.

For example, a configuration may be employed where the plurality of measurement modes include: a first measurement mode in which the impedance of the battery cell 42D (corresponding to at least one predetermined battery cell) among the plurality of battery cells 42 is measured; and a second measurement mode in which the impedances of the battery cells 42A, 42D and 42G (corresponding to more battery cells than the at least one predetermined battery cell) among the plurality of battery cells 42 are measured. With such a configuration, it will be possible to make the measurement accuracy, the measurement time and the electric current consumption of the secondary battery different between the first measurement mode in which the impedance of the battery cell 42D is measured and the second measurement mode in which the impedances of the battery cells 42A, 42D and 42G are measured.

Among the battery cells 42A to 42G included in each battery module 41, the central battery cell 42D has the highest temperature because it is difficult for heat to be dissipated from it to its surroundings. Therefore, the battery cell 42D is more prone to deterioration than the other battery cells 42. In this regard, the at least one predetermined battery cell on which the impedance measurement is performed in the first measurement mode may be set to the battery cell 42D whose temperature is highest among the plurality of battery cells 42A to 42G. Consequently, it will be possible to measure the impedance of the battery cell 42D, which is prone to deterioration, in the first measurement mode; the number of battery cells 42 on which the impedance measurement is performed is set to be smaller in the first measurement mode than in the second measurement mode. Thus, even with the smaller number of battery cells 42 on which the impedance measurement is performed in the first measurement mode, it will still be possible to suppress decrease in the accuracy of monitoring deterioration of each battery module 41 (or the battery pack 40).

The second embodiment may also be implemented through the following modifications. It should be noted that: parts in the following modifications identical to those in the first and second embodiments are designated by the same reference signs as those in the first and second embodiments; and description of these parts will be omitted.

In some cases, the battery cells 42A and 42G whose temperatures are lowest among the plurality of battery cells 42 may be more prone to deterioration than the other battery cells 42. In these cases, the at least one predetermined battery cell on which the impedance measurement is performed in the first measurement mode may be set to the battery cells 42A and 42G whose temperatures are lowest among the plurality of battery cells 42. Moreover, in the second measurement mode, the battery measurement unit 50 may measure the impedances of the battery cells 42A, 42D and 42G.

With the above configuration, it will be possible to measure the impedances of the battery cells 42A and 42G, which are prone to deterioration, in the first measurement mode in which the number of battery cells 42 on which the impedance measurement is performed is smaller than that in the second measurement mode. Thus, even with the smaller number of battery cells 42 on which the impedance measurement is performed in the first measurement mode, it will still be possible to suppress decrease in the accuracy of monitoring deterioration of each battery module 41 (or the battery pack 40). In addition, it is also possible to: measure the impedances of the battery cells 42A and 42G in the first measurement mode; switch the measurement mode from the first measurement mode to the second measurement mode when the absolute value of the difference between the impedances of the battery cells 42A and 42G is greater than a threshold value; and measure the impedances of all the battery cells 42A to 42G in the second measurement mode.

It should be noted that the battery cell(s) 42 whose temperature(s) is (are) highest or lowest among the plurality of battery cells 42 may be determined through actual measurement of the temperatures of the battery cells 42 or preset based on test results or the like.

Among the plurality of battery cells 42A to 42G, the battery cell 42D whose temperature change is greatest is more prone to deterioration than the other battery cells 42. Therefore, a configuration may be employed where the at least one predetermined battery cell is set to be the battery cell 42D whose temperature change is greatest among the plurality of battery cells 42A to 42G. With such a configuration, even with the smaller number of battery cells 42 on which the impedance measurement is performed in the first measurement mode, it will still be possible to suppress decrease in the accuracy of monitoring deterioration of the secondary battery. It should be noted that depending on the characteristics and arrangement environment of each battery module 41, the battery cell 42 whose temperature change is greatest among the plurality of battery cells 42A to 42G may be other than the battery cell 42D. It also should be noted that the battery cell 42 whose temperature change is greatest among the plurality of battery cells 42A to 42G may be determined through actual measurement of the temperatures of the battery cells 42 or preset based on test results or the like.

An equalization process may be performed for the plurality of battery cells 42A to 42G to equalize the SOCs of the battery cells 42. In this case, among the plurality of battery cells 42A to 42G, the battery cell 42 on which the equalization process has been performed the greatest number of times may have been more deteriorated than the other battery cells 42. Otherwise, the battery cell 42 on which the equalization process has been performed the least number of times may have been more deteriorated and thus reduced in full-charge capacity by more than the other battery cells 42. Therefore, a configuration may be employed where the at least one predetermined battery cell is set to be the battery cell 42 on which the equalization process has been performed the greatest number of times or the least number of times among the plurality of battery cells 42A to 42G. With such a configuration, even with the smaller number of battery cells 42 on which the impedance measurement is performed in the first measurement mode, it will still be possible to suppress decrease in the accuracy of monitoring deterioration of the secondary battery.

Among the plurality of battery cells 42A to 42G, the battery cell 42 whose voltage change is greatest may be more prone to deteriorate than the other battery cells 42. Therefore, a configuration may be employed where the at least one predetermined battery cell is set to be the battery cell 42 whose voltage change is greatest among the plurality of battery cells 42A to 42G. With such a configuration, even with the smaller number of battery cells 42 on which the impedance measurement is performed in the first measurement mode, it will still be possible to suppress decrease in the accuracy of monitoring deterioration of the secondary battery. It should be noted that the battery cell 42 whose SOC change is greatest among the plurality of battery cells 42A to 42G may be used as the battery cell 42 whose voltage change is greatest.

Among the plurality of battery cells 42A to 42G, the battery cell 42 whose resistance is highest may have been more deteriorated than the other battery cells 42. Therefore, a configuration may be employed where the at least one predetermined battery cell is set to be the battery cell 42 whose resistance is highest among the plurality of battery cells 42A to 42G. With such a configuration, even with the smaller number of battery cells 42 on which the impedance measurement is performed in the first measurement mode, it will still be possible to suppress decrease in the accuracy of monitoring deterioration of the secondary battery.

Among the plurality of battery cells 42A to 42G, the battery cell 42D which is located at the center (or predetermined position) may have been more deteriorated than the other battery cells 42. Therefore, a configuration may be employed where the at least one predetermined battery cell is set to be the battery cell 42D which is located at the center among the plurality of battery cells 42A to 42G. With such a configuration, even with the smaller number of battery cells 42 on which the impedance measurement is performed in the first measurement mode, it will still be possible to suppress decrease in the accuracy of monitoring deterioration of the secondary battery. It should be noted that depending on the characteristics and arrangement environment of each battery module 41, the at least one predetermined battery cell may be set to be a battery cell 42 located at a position other than the center. Alternatively, it is possible to: perform the impedance measurement on the at least one predetermined battery cell, which is set to be the odd-numbered battery cells 42 or the even-numbered battery cells 42, in the first measurement mode; and measure the impedances of all the battery cells 42A to 42G in the second measurement mode.

### Third Embodiment

Hereinafter, a third embodiment will be described with reference to the drawings, focusing on the differences thereof from the first and second embodiments. It should be noted that: parts in the third embodiment identical to those in the first and second embodiments are designated by the same reference signs as those in the first and second embodiments; and description of these parts will be omitted.

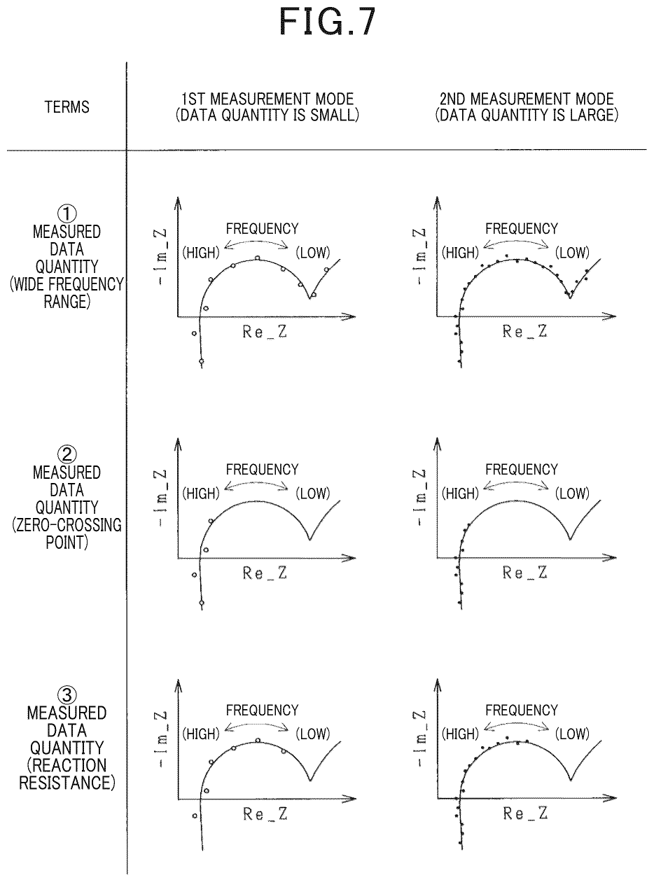

In the present embodiment, as shown in FIG. 7, the battery measurement unit 50 measures the impedance of the battery cell 42 while changing the measurement frequency, and creates a complex impedance plane plot. In the complex impedance plane plot, the horizontal axis represents the real part of the impedance, whereas the vertical axis represents the imaginary part of the impedance.

The electric current consumption of the battery cell 42 varies depending on the quantity of data acquired during the measurement of the impedance. In this regard, in the present embodiment, the plurality of measurement modes differ in, as the measurement condition, quantity of data acquired during the measurement of the impedance. Moreover, the battery control ECU 70 switches the measurement mode between the plurality of measurement modes based on a comparison between a correlating parameter, which correlates with the impedance, and a threshold value. Consequently, by comparing the correlating parameter with the threshold value, it becomes possible to switch the measurement mode to a proper one of the plurality of measurement modes differing in quantity of data acquired during the measurement of the impedance.

For example, a configuration may be employed where the plurality of measurement modes include: a first measurement mode in which the impedance is measured with respect to at least one predetermined frequency; and a second measurement mode in which the impedance is measured with respect to more frequencies than the at least one predetermined frequency. In the upper part of FIG. 7, the impedance is measured with respect to frequencies in a wide range from low to high frequencies; and the impedance is measured with respect to more frequencies in the second measurement mode than in the first measurement mode. In the middle part of FIG. 7, the impedance is measured with respect frequencies in the vicinity of the zero-crossing point; and the impedance is measured with respect to more frequencies in the second measurement mode than in the first measurement mode. It should be noted that the real part of the impedance at the zero-crossing point mainly represents the solution resistance that is the resistance when electric charge moves through the solution in the battery cell 42. In the lower part of FIG. 7, the impedance is measured with respect frequencies for estimating the radius (or diameter) of the arc section of the impedance curve regarding the real part; and the impedance is measured with respect to more frequencies in the second measurement mode than in the first measurement mode. It should be noted that the diameter of the arc section regarding the real part mainly represents the reaction resistance that is the resistance when molecules leave the electrodes and enter the solution in the battery cell 42.

With the above configuration, it will be possible to make the measurement accuracy, the measurement time and the electric current consumption of the battery cell 42 different between the first measurement mode in which the impedance is measured with respect to the at least one predetermined frequency and the second measurement mode in which the impedance is measured with respect to more frequencies than the at least one predetermined frequency. Moreover, by comparing the correlating parameter with the threshold value, it will be possible to switch the measurement mode to a proper one of the first and second measurement modes. For example, in the first measurement mode, the measurement time can be shortened and the electric current consumption of the battery cell 42 can be reduced by measuring the impedance with respect to a smaller number of frequencies; in the second measurement mode, the measurement accuracy can be improved by measuring the impedance with respect to a larger number of frequencies.

The third embodiment may also be implemented through the following modifications. It should be noted that: parts in the following modifications identical to those in the first, second and third embodiments are designated by the same reference signs as those in the first, second and third embodiments; and description of these parts will be omitted.

A configuration may be employed where the battery control ECU 70 switches the measurement mode to the first measurement mode when the battery cell 42 is not determined to be abnormal, and switches the measurement mode to the second measurement mode when the battery cell 42 is determined in the first measurement mode to be abnormal. With such a configuration, when the battery cell 42 is determined in the first measurement mode to be abnormal, it will be possible to switch the measurement mode to the second measurement mode in which the impedance of the battery cell 42 is measured with respect to more frequencies, thereby improving the measurement accuracy. On the other hand, when the battery cell 42 is not determined to be abnormal, it will be possible to measure the impedance of the battery cell 42 with respect to fewer frequencies in the first measurement mode, thereby shortening the measurement time and reducing the electric current consumption of the battery cell 42.

A configuration may be employed where in the second measurement mode, the impedance is measured with respect to frequencies within a measurement range depending on the content of abnormality. With such a configuration, it will be possible to set, according to the content of abnormality, the range of frequencies for measuring the impedance in the second measurement mode, thereby facilitating ascertainment of the cause of the abnormality. For example, the range of measurement frequencies may be changed according to the content of abnormality, as shown in the upper, middle and lower parts of FIG. 7.

A configuration may be employed where in the second measurement mode, a frequency at which the impedance satisfies a predetermined condition is searched. With such a configuration, when the battery cell 42 is determined to be abnormal, it will be possible to ascertain the frequency at which the impedance satisfies the predetermined condition. For example, in the second measurement mode, the frequency may be searched at which the impedance becomes a zero-crossing point as shown in the middle part of FIG. 7.

The characteristics of the battery cell 42 can be predicted to some extent based on a correlating parameter other than the impedance. Therefore, a configuration may be employed where the at least one predetermined frequency, with respect to which the impedance is measured in the first measurement mode, is at least one frequency set based on a correlating parameter other than the impedance. With such a configuration, the at least one predetermined frequency can be properly set upon predication of the characteristics of the battery cell 42; consequently, decrease in the measurement accuracy can be suppressed even in the first measurement mode in which the quantity of data acquired during the measurement of the impedance is smaller than that in the second measurement mode. For example, as a correlating parameter other than the impedance, the state of charge (SOC) of the battery cell 42, the state of health (SOH) of the battery cell 42, the temperature of the battery cell 42 or the like may be used.

The impedance measurement condition suitable for ascertaining the characteristics of the battery cell 42 changes depending on the state of the battery cell 42. Moreover, the state of the battery cell 42 can be estimated based on the impedance. Therefore, a configuration may be employed where the at least one predetermined frequency is at least one frequency set based on the state of the battery cell 42 that is estimated based on the impedance. For example, the temperature of the battery cell 42 may be estimated based on the shape and position of the impedance curve in the complex impedance plane plot; and the at least one predetermined frequency may be set based on the estimated temperature of the battery cell 42. With such a configuration, the at least one predetermined frequency in the first measurement mode can be properly set upon estimation of the state of the battery cell 42 based on the impedance. Consequently, decrease in the measurement accuracy can be suppressed even in the first measurement mode in which the quantity of data acquired during the measurement of the impedance is smaller than that in the second measurement mode.

A configuration may be employed where the plurality of measurement modes include: a first measurement mode in which the impedance is measured at a predetermined period; and a second measurement mode in which the impedance is measured at a period shorter than the predetermined period.

With the above configuration, it will be possible to make the measurement accuracy, the measurement time and the electric current consumption of the battery cell 42 different between the first measurement mode in which the impedance is measured at a predetermined period and the second measurement mode in which the impedance is measured at a period shorter than the predetermined period. Moreover, by comparing the correlating parameter with the threshold value, it will be possible to switch the measurement mode to a proper one of the first and second measurement modes. For example, in the case of the measurement time being the same, in the first measurement mode, the electric current consumption of the battery cell 42 can be reduced by measuring the impedance at a longer period; in the second measurement mode, the measurement accuracy can be improved by measuring the impedance at a shorter period. Otherwise, in the case of the number of measurements being the same, in the second measurement mode, the measurement time can be shortened by measuring the impedance at the shorter period.

A configuration may be employed where the at least one predetermined frequency is at least one frequency at which the impedance satisfies a predetermined condition. For example, the at least one predetermined frequency may include a frequency at which the impedance becomes a zero-crossing point as shown in the middle part of FIG. 7. With such a configuration, it will be possible to measure, in the first measurement mode, the impedance with respect to the at least one frequency at which the impedance satisfies the predetermined condition. Moreover, it will become easier to ascertain the characteristics of the battery cell 42 even in the first measurement mode in which the quantity of data acquired during the measurement of the impedance is smaller than that in the second measurement mode. It should be noted that the at least one frequency at which the impedance satisfies the predetermined condition may be searched through measurement of the impedance of the battery cell 42 or preset based on test results or the like.

The above-described first to third embodiments and modifications thereof may be further modified as follows. It should be noted that: parts in the following modifications identical to those in the first, second and third embodiments are designated by the same reference signs as those in the first, second and third embodiments; and description of these parts will be omitted.

The battery control ECU 70 may be further configured to switch the measurement mode in response to a change in the relationship between the impedance and a characteristic of the battery cell 42 other than the impedance. For example, the measurement mode may be switched in response to a change in the relationship between the temperature of the battery cell 42 and the shape and position of the impedance curve in the complex impedance plane plot. With such a configuration, the measurement mode can be switched in response to a change in the characteristic of the battery cell 42 relating to the impedance.

The battery control ECU 70 may be further configured to switch the measurement mode according to the state of the surrounding environment of the battery cell 42. With such a configuration, even when there is a change in the state of the surrounding environment of the battery cell 42, it will still be possible to switch the measurement mode to a proper measurement mode. For example, the measurement mode may be switched according to the external pressure and/or outside air temperature of the battery cell 42 (or the battery module 41, the battery pack 40).

The battery control ECU 70 may be further configured to switch the measurement mode based on a predetermined schedule. With such a configuration, the measurement mode can be switched based on the predetermined schedule regardless of the state of the battery cell 42. For example, the measurement mode may be switched to the first measurement mode when measuring the impedance of the battery cell 42 at regular charge/discharge intervals or at regular time intervals, and to the second measurement mode during the startup and shutdown of the electric power supply system 10.

The battery control ECU 70 may be further configured to switch the measurement mode based on the usage history of the battery cell 42. With such a configuration, the measurement mode can be switched to a proper measurement mode taking into account the usage history of the battery cell 42. For example, the measurement mode may normally be set to the first measurement mode; when discharge at high electric power (i.e., electric power higher than a predetermined electric power) has continued for longer than a predetermined time, the measurement mode may be switched from the first measurement mode to the second measurement mode.

The battery control ECU 70 may be further configured to be capable of changing, based on predetermined information, the condition for switching the measurement mode. With such a configuration, the condition for switching the measurement mode can be changed based on the predetermined information, rather than being fixed. For example, in the case of switching the measurement mode based on a comparison between a correlating parameter, which correlates with impedance, and a threshold value, the battery control ECU 70 may change the threshold value based on the predetermined information.

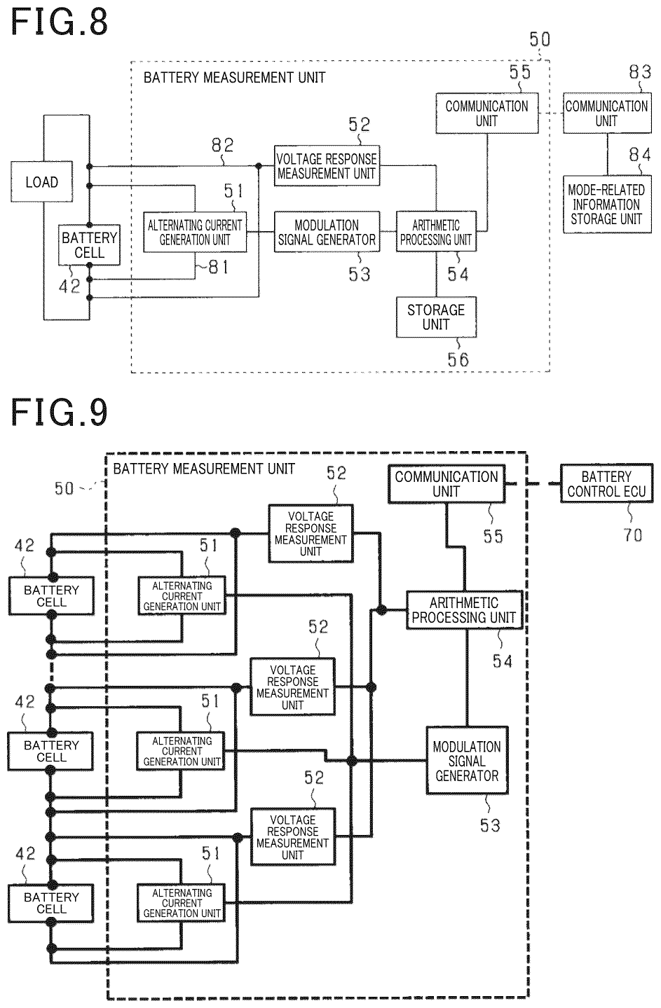

Each battery measurement unit 50 may be configured to further include a mode change unit that changes, based on predetermined information, the contents of the plurality of measurement modes differing in the measurement condition. With such a configuration, the contents of the plurality of measurement modes can be changed based on the predetermined information, rather than being fixed. For example, as shown in FIG. 8, the mode change unit may be realized by the arithmetic processing unit 54 and a storage unit 56 connected with the arithmetic processing unit 54. The storage unit 56 stores the contents of the plurality of measurement modes differing in the measurement condition; and the contents of the plurality of measurement modes can be rewritten. The arithmetic processing unit 54 reads new contents of the plurality of measurement modes from a mode-related information storage unit 84 through communication via the communication units 55 and 83, and rewrites the contents of the plurality of measurement modes stored in the storage unit 56 with the new contents.

The storage unit 56 may be configured to be incapable of being externally connected (i.e., configured to be stand-alone). With such a configuration, after storing the predetermined information in the storage unit 56 during the initial setting, it will be possible to prevent the predetermined information from being stolen by hacking or the like and thus possible to prevent the condition for switching the measurement mode and/or the contents of the plurality of measurement modes from being unintentionally changed.

A configuration may be employed where the aforementioned predetermined information is information on the usage history of the battery cell 42. With such a configuration, it will be possible to suitably change, taking into account the usage history of the battery cell 42, the condition for switching the measurement mode and/or the contents of the plurality of measurement modes.

Referring to FIG. 8, the mode-related information storage unit 84 may be arranged outside the impedance measurement apparatus (i.e., the battery measurement unit 50 and the battery control ECU 70). In other words, a configuration may be employed where the predetermined information is acquired from outside the impedance measurement apparatus through communication. With such a configuration, it will be possible to suitably change, taking into account the predetermined information acquired from outside the impedance measurement apparatus through communication, the condition for switching the measurement mode and/or the contents of the plurality of measurement modes. For example, the mode-related information storage unit 84 may update the predetermined information based on big data such as the results of measuring the impedances of battery packs 40 installed in vehicles on the market.

Specifically, the mode-related information storage unit 84 may be provided in an external server connected with the battery measurement unit 50 via the Internet. In other words, a configuration may be employed where the predetermined information is stored in an external server connected with the battery measurement unit 50 (or the impedance measurement apparatus) via the Internet. With such a configuration, it will be possible to acquire the predetermined information from the external server connected with the battery measurement unit 50 via the Internet. Moreover, a configuration may be employed where the predetermined information is acquired only when the impedance measurement apparatus is electrically connected externally. For example, the predetermined information may be acquired only when a service tool is connected with the impedance measurement apparatus.

As shown in FIG. 9, each battery measurement unit 50 may include an alternating current generation unit 51 and a voltage response measurement unit 52 for each battery cell 42. Moreover, with the battery cells 42 being the measurement targets, alternating currents may be caused by the respective alternating current generation units 51 to flow from the battery cells 42 individually or simultaneously; and the voltage variations of the battery cells 42 may be measured by the respective voltage response measurement units 52.

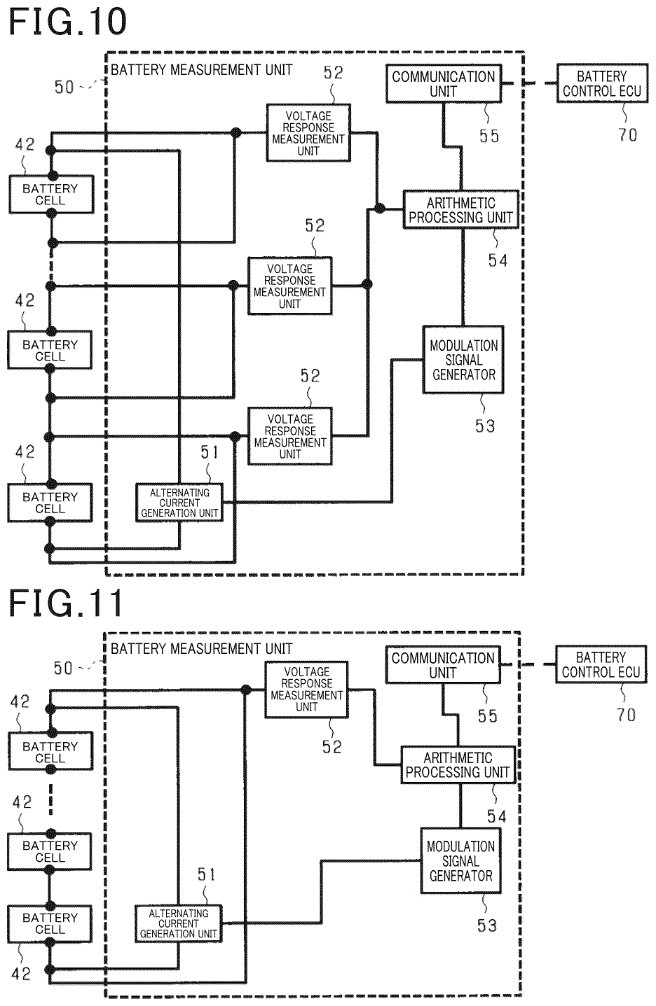

Alternatively, as shown in FIG. 10, each battery measurement unit 50 may include a single alternating current generation unit 51 for all the battery cells 42 and a plurality of voltage response measurement units 52 for the respective battery cells 42. Moreover, with the battery cells 42 being the measurement targets, alternating currents may be caused by the single alternating current generation unit 51 to flow from the battery cells 42; and the voltage variations of the battery cells 42 may be measured by the respective voltage response measurement units 52.

Alternatively, as shown in FIG. 11, the battery measurement unit 50 may include a single alternating current generation unit 51 and a single voltage response measurement unit 52 for all the battery cells 42. Moreover, with the battery cells 42 being the measurement targets, alternating currents may be caused by the single alternating current generation unit 51 to flow from the battery cells 42; and the voltage variations of the battery cells 42 may be measured by the single voltage response measurement unit 52.

Alternating current may be caused to flow from each battery module 41 as a whole; and either the voltage variations of the battery cells 42 of each battery module 41 or the voltage variation of each battery module 41 as a whole may be measured. Alternatively, alternating current may be caused to flow from the battery pack 40 as a whole; and either the voltage variations of the battery cells 42 of the battery modules 41 of the battery pack 40 or the voltage variation of the battery pack 40 as a whole may be measured.

The above-described first embodiment and modifications thereof, the above-described second embodiment and modifications thereof, and the above-described third embodiment and modifications thereof may also be implemented in combination.

In the case of the first and second embodiments being combined with each other, the plurality of measurement modes may differ in, as the measurement condition, both method of measuring the impedance by the battery measurement unit 50 and number of the battery cells 42 on which impedance measurement is performed. Consequently, by comparing the correlating parameter with the threshold value, it will become possible to switch the measurement mode to a proper one of the plurality of measurement modes differing in both method of measuring the impedance and number of the battery cells 42 on which impedance measurement is performed.

In the case of the first and third embodiments being combined with each other, the plurality of measurement modes may differ in, as the measurement condition, both method of measuring the impedance by the battery measurement unit 50 and quantity of data acquired during the measurement of the impedance. Consequently, by comparing the correlating parameter with the threshold value, it will become possible to switch the measurement mode to a proper one of the plurality of measurement modes differing in both method of measuring the impedance and quantity of data acquired during the measurement of the impedance.

In the case of the second and third embodiments being combined with each other, the plurality of measurement modes may differ in, as the measurement condition, both number of the battery cells 42 on which impedance measurement is performed and quantity of data acquired during the measurement of the impedance. Consequently, by comparing the correlating parameter with the threshold value, it will become possible to switch the measurement mode to a proper one of the plurality of measurement modes differing in both number of the battery cells 42 on which impedance measurement is performed and quantity of data acquired during the measurement of the impedance.

In the case of the first, second and third embodiments being combined with each other, the plurality of measurement modes may differ in, as the measurement condition, method of measuring the impedance by the battery measurement unit 50, number of the battery cells 42 on which impedance measurement is performed and quantity of data acquired during the measurement of the impedance. Consequently, by comparing the correlating parameter with the threshold value, it will become possible to switch the measurement mode to a proper one of the plurality of measurement modes differing in method of measuring the impedance by the battery measurement unit 50, number of the battery cells 42 on which impedance measurement is performed and quantity of data acquired during the measurement of the impedance.

A switching unit, which switches the measurement mode based on a comparison between a correlating parameter that correlates with impedance and a threshold value, may be provided in each battery measurement unit 50 (e.g., in the arithmetic processing unit 54 thereof). In this case, each battery measurement unit 50 will constitute an impedance measurement apparatus for a secondary battery. In addition, the alternating current generation unit 51 may alternatively be provided in a charger or the like outside the vehicle.

The electric power supply system 10 is not limited to being installed in a vehicle, but may alternatively be installed in an electric aircraft, an electric ship or the like.

While the present disclosure has been described pursuant to the embodiments, it should be appreciated that the present disclosure is not limited to the embodiments and the structures. Instead, the present disclosure encompasses various modifications and changes within equivalent ranges. In addition, various combinations and modes are also included in the category and the scope of technical idea of the present disclosure.

1. An impedance measurement apparatus for measuring impedance of a secondary battery, the impedance measurement apparatus comprising:
a measurement unit capable of measuring the impedance of the secondary battery using a plurality of measurement modes differing in measurement condition; and
a switching unit configured to switch between the plurality of measurement modes based on a comparison between a correlating parameter, which correlates with the impedance of the secondary battery, and a threshold value.

2. The impedance measurement apparatus as set forth in claim 1, wherein
the plurality of measurement modes differ in, as the measurement condition, method of measuring the impedance of the secondary battery by the measurement unit.

3. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, number of times of causing, by the current generation unit, the alternating current to be outputted from the secondary battery and measuring the voltage of the secondary battery by the voltage measurement unit.

4. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, number of bits of a digital value obtained by an AD conversion of an analog value of the voltage of the secondary battery measured by the voltage measurement unit.

5. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, cutoff frequency of a low-pass filter that cuts off frequency components of the voltage of the secondary battery measured by the voltage measurement unit which are higher than the cutoff frequency.

6. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, waveform of the alternating current caused by the current generation unit to be outputted from the secondary battery.

7. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, magnitude of the alternating current caused by the current generation unit to be outputted from the secondary battery.

8. The impedance measurement apparatus as set forth in claim 2, wherein
the measurement unit includes:
a current generation unit configured to cause alternating current to be outputted from the secondary battery; and
a voltage measurement unit configured to measure a voltage of the secondary battery responding to the alternating current,
the plurality of measurement modes differ in, as the measurement condition, manner of correcting the voltage of the secondary battery measured by the voltage measurement unit.

9. The impedance measurement apparatus as set forth in claim 2, wherein
the plurality of measurement modes differ in, as the measurement condition, temperature at which the impedance of the secondary battery is measured by the measurement unit.

10. The impedance measurement apparatus as set forth in claim 2, wherein
the secondary battery includes a plurality of battery cells,
the measurement unit includes:
current generation units configured to cause alternating currents to be outputted from the respective battery cells; and
voltage measurement units configured to measure voltages of the secondary battery responding to the respective alternating currents,
the plurality of measurement modes differ in, as the measurement condition, number of the current generation units and the voltage measurement units operated simultaneously.

11. The impedance measurement apparatus as set forth in claim 1, wherein
the secondary battery includes a plurality of battery cells, and
the plurality of measurement modes differ in, as the measurement condition, number of the battery cells on which impedance measurement is performed.

12. The impedance measurement apparatus as set forth in claim 2, wherein
the secondary battery includes a plurality of battery cells, and
the plurality of measurement modes further differ in, as the measurement condition, number of the battery cells on which impedance measurement is performed.

13. The impedance measurement apparatus as set forth in claim 11, wherein
the plurality of measurement modes include:
a first measurement mode in which the impedance measurement is performed on at least one predetermined battery cell among the plurality of battery cells; and
a second measurement mode in which the impedance measurement is performed on more battery cells than the at least one predetermined battery cell among the plurality of battery cells.

14. The impedance measurement apparatus as set forth in claim 13, wherein
the at least one predetermined battery cell is at least one battery cell whose temperature is highest or lowest among the plurality of battery cells.

15. The impedance measurement apparatus as set forth in claim 13, wherein
the at least one predetermined battery cell is at least one battery cell whose temperature change is greatest among the plurality of battery cells.

16. The impedance measurement apparatus as set forth in claim 13, wherein
an equalization process is performed to equalize residual capacities of the plurality of battery cells, and
the at least one predetermined battery cell is at least one battery cell on which the equalization process has been performed a greatest number of times or a least number of times among the plurality of battery cells.

17. The impedance measurement apparatus as set forth in claim 13, wherein
the at least one predetermined battery cell is at least one battery cell whose voltage change is greatest among the plurality of battery cells.

18. The impedance measurement apparatus as set forth in claim 13, wherein
the at least one predetermined battery cell is at least one battery cell whose resistance is highest among the plurality of battery cells.

19. The impedance measurement apparatus as set forth in claim 13, wherein
the at least one predetermined battery cell is at least one battery cell which is located at a predetermined position among the plurality of battery cells.

20. The impedance measurement apparatus as set forth in claim 1, wherein
the plurality of measurement modes differ in, as the measurement condition, quantity of data acquired during measurement of the impedance.

21. The impedance measurement apparatus as set forth in claim 2, wherein
the plurality of measurement modes further differ in, as the measurement condition, quantity of data acquired during measurement of the impedance.

22. The impedance measurement apparatus as set forth in claim 11, wherein
the plurality of measurement modes further differ in, as the measurement condition, quantity of data acquired during measurement of the impedance.

23. The impedance measurement apparatus as set forth in claim 12, wherein
the plurality of measurement modes further differ in, as the measurement condition, quantity of data acquired during measurement of the impedance.

24. The impedance measurement apparatus as set forth in claim 20, wherein
the plurality of measurement modes include:
a first measurement mode in which the impedance is measured with respect to at least one predetermined frequency; and
a second measurement mode in which the impedance is measured with respect to more frequencies than the at least one predetermined frequency.

25. The impedance measurement apparatus as set forth in claim 24, wherein
the switching unit is configured to:
switch the measurement mode to the first measurement mode when the secondary battery is not determined to be abnormal; and
switch the measurement mode to the second measurement mode when the secondary battery is determined in the first measurement mode to be abnormal.

26. The impedance measurement apparatus as set forth in claim 25, wherein
in the second measurement mode, the impedance is measured with respect to frequencies within a measurement range depending on content of abnormality.

27. The impedance measurement apparatus as set forth in claim 25, wherein
in the second measurement mode, a frequency at which the impedance satisfies a predetermined condition is searched.

28. The impedance measurement apparatus as set forth in claim 24, wherein
the at least one predetermined frequency is at least one frequency set based on the correlating parameter other than the impedance.

29. The impedance measurement apparatus as set forth in claim 24, wherein
the at least one predetermined frequency is at least one frequency set based on a state of the secondary battery estimated based on the impedance.

30. The impedance measurement apparatus as set forth in claim 20, wherein
the plurality of measurement modes include:
a first measurement mode in which the impedance is measured at a predetermined period; and
a second measurement mode in which the impedance is measured at a period shorter than the predetermined period.

31. The impedance measurement apparatus as set forth in claim 24, wherein
the at least one predetermined frequency is at least one frequency at which the impedance satisfies a predetermined condition.

32. The impedance measurement apparatus as set forth in claim 1, wherein
the switching unit is configured to switch between the plurality of measurement modes when the correlating parameter exceeds the threshold value.

33. The impedance measurement apparatus as set forth in claim 1, wherein
the switching unit is further configured to switch between the plurality of measurement modes in response to a change in the relationship between the impedance and a characteristic of the secondary battery other than the impedance.

34. The impedance measurement apparatus as set forth in claim 1, wherein
the switching unit is further configured to switch between the plurality of measurement modes according to a state of a surrounding environment of the secondary battery.

35. The impedance measurement apparatus as set forth in claim 1, wherein
the switching unit is further configured to switch between the plurality of measurement modes based on a predetermined schedule.

36. The impedance measurement apparatus as set forth in claim 1, wherein
the switching unit is further configured to switch between the plurality of measurement modes based on usage history of the secondary battery.

37. The impedance measurement apparatus as set forth in claim 1, wherein
the switching unit is capable of changing, based on predetermined information, condition for switching between the plurality of measurement modes.

38. The impedance measurement apparatus as set forth in claim 1, wherein
the measurement unit includes a mode change unit configured to change, based on predetermined information, contents of the plurality of measurement modes.

39. The impedance measurement apparatus as set forth in claim 37, wherein
the predetermined information is information on the usage history of the secondary battery.

40. The impedance measurement apparatus as set forth in claim 37, wherein
the predetermined information is acquired from outside the impedance measurement apparatus through communication.

41. The impedance measurement apparatus as set forth in claim 40, wherein
the predetermined information is stored in an external server connected with the impedance measurement apparatus via the Internet.

42. The impedance measurement apparatus as set forth in claim 37, wherein
the predetermined information is acquired only when the impedance measurement apparatus is electrically connected externally.
